(19) United States
(12) Patent Application Publication
(10) Pub. No.: US 2022/0293450 A1
(43) Pub. Date: Sep. 15, 2022

(54) SEMICONDUCTOR MANUFACTURING APPARATUS AND METHOD OF MANUFACTURING SEMICONDUCTOR DEVICE

(71) Applicant: Kioxia Corporation, Tokyo (JP)

(72) Inventor: Yuji SETTA, Kuwana Mie (JP)

(73) Assignee: Kioxia Corporation, Tokyo (JP)

(21) Appl. No.: 17/463,847

(22) Filed: Sep. 1, 2021

(30) Foreign Application Priority Data
Mar. 12, 2021 (JP) 2021-040511

(51) Int. Cl. H01L 21/687

(52) U.S. Cl. CPC H01L 21/68735; H01L 25/18

(57) ABSTRACT

A semiconductor manufacturing apparatus includes a stage configured to mount a wafer on a mounting surface. A blade is configured to cut an outer circumference portion of the wafer toward the mounting surface. The stage includes a protrusion portion provided at a position corresponding to a first region where a material film is not formed on a first surface of the outer circumference portion of the wafer facing the mounting surface.

### CROSS-REFERENCE TO RELATED APPLICATION

This application is based upon and claims the benefit of priority from Japanese Patent Application No. 2021-040511, filed Mar. 12, 2021, the entire contents of which are incorporated herein by reference.

### FIELD

Embodiments described herein relate generally to a semiconductor manufacturing apparatus and a method of manufacturing a semiconductor device.

### BACKGROUND

There is disclosed a method of electrically connecting semiconductor elements to each other by forming a semiconductor element on each of a plurality of semiconductor wafers and bonding the semiconductor wafers to each other. Before or after bonding the semiconductor wafers to each other, a step of cutting (trimming) edge portions of the semiconductor wafers is performed.

However, due to the effect of unevenness of a surface of the semiconductor wafer, a load locally concentrates on the semiconductor wafer such that the edge of the semiconductor wafer may crack or chip during cutting.

### DESCRIPTION OF THE DRAWINGS

FIG. 1 is a schematic front view illustrating a configuration example of a cutting apparatus according to a first embodiment;

FIG. 2 is a schematic plan view illustrating the configuration example of the cutting apparatus according to the first embodiment;

FIG. 3A is a schematic plan view illustrating a wafer having a contact trace of a holding tool of a film forming apparatus;

FIG. 3B is a schematic cross-sectional view taken along line B-B of FIG. 3A;

FIG. 4 is a schematic cross-sectional view illustrating a state of a trimming step of a bonded wafer according to the first embodiment;

FIG. 5 is a schematic perspective view illustrating the state of the trimming step of the bonded wafer according to the first embodiment;

FIG. 6 is schematic perspective view illustrating a configuration example of a pad;

FIG. 7 is a schematic cross-sectional view illustrating a state of a trimming step in a comparative example;

FIG. 8 is a schematic cross-sectional view illustrating a state of a trimming step in a comparative example;

FIG. 9A is a schematic plan view illustrating a configuration example of a stage according to the first embodiment;

FIG. 9B is a cross-sectional view taken along line B-B of FIG. 9A;

FIG. 10 is a schematic cross-sectional view illustrating a step after trimming an outer circumference portion;

FIG. 11 is a schematic cross-sectional view illustrating a step after trimming an outer circumference portion;

FIG. 12 is a schematic cross-sectional view illustrating a step after trimming an outer circumference portion;

FIG. 13 is a schematic cross-sectional view illustrating an example of an internal configuration of a broken line frame B13 of FIG. 12;

FIG. 14 is a schematic cross-sectional view illustrating a configuration example of a stage according to a modification example of the first embodiment;

FIG. 15 is a schematic perspective view illustrating a state of a trimming step of a wafer using a cutting apparatus according to a second embodiment;

FIG. 16 is a schematic plan view illustrating a configuration example of a stage according to the second embodiment;

FIG. 17 is a schematic front view illustrating a configuration example of a cutting apparatus according to a third embodiment;

FIG. 18 is a schematic plan view illustrating a configuration example of a stage according to the third embodiment; and

FIG. 19 is a schematic perspective view illustrating a state of a trimming step of a bonded wafer according to the third embodiment.

### DETAILED DESCRIPTION

Embodiments provide a semiconductor manufacturing apparatus that reduces cracking or chipping of a semiconductor wafer during cutting of an edge portion of the semiconductor wafer and a method of manufacturing a semiconductor device.

In general, according to at least one embodiment, provided is a semiconductor manufacturing apparatus including a stage configured to mount a wafer on a mounting surface. A blade is configured to cut an outer circumference portion of the wafer toward the mounting surface. The stage includes a protrusion portion provided at a position corresponding to a first region where a material film is not formed on a first surface of the outer circumference portion of the wafer facing the mounting surface.

Hereinafter, embodiments will be described with reference to the drawings. The embodiments do not limit the present disclosure. The drawings are schematic or conceptual, in which a ratio between components, and the like are not necessarily the same as the actual ones. In the specification and the drawings, the same components as described above with reference to the previous drawings are represented by the same reference numerals, and the detailed description thereof will not be repeated.

### First Embodiment

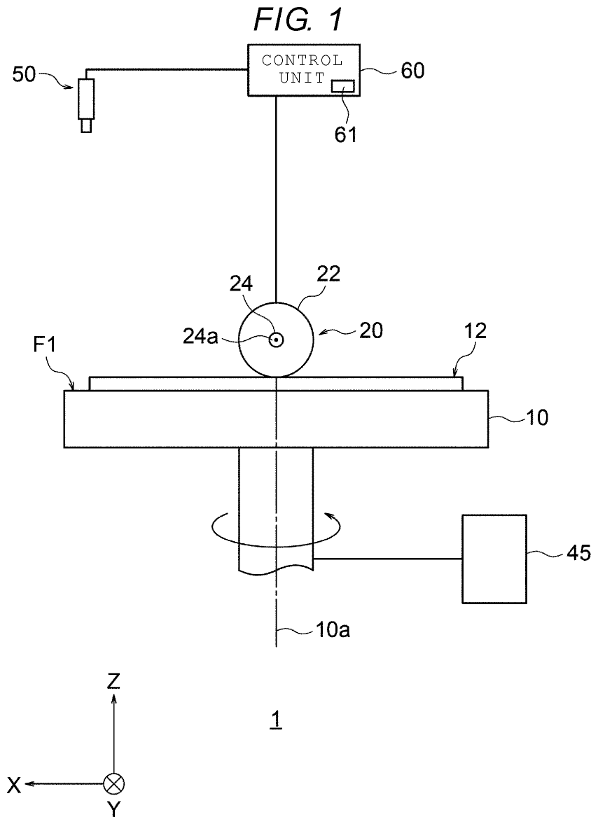

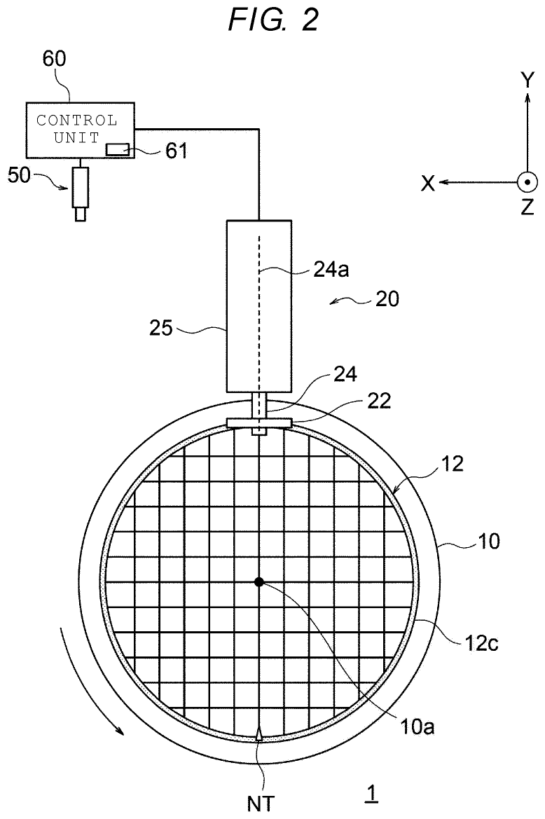

FIG. 1 is a schematic front view illustrating a configuration example of a cutting apparatus 1 according to a first embodiment. FIG. 2 is a schematic plan view illustrating the configuration example of the cutting apparatus 1.

The cutting apparatus 1 as the semiconductor manufacturing apparatus includes a stage 10, a cutting unit 20, a control unit 60 (controller), a stage driving unit 45 (driver), and an imaging unit 50. A direction (vertical direction) substantially perpendicular to a mounting surface F1 of the stage 10 is a Z direction. An X direction and a Y direction are perpendicular to each other in a surface (horizontal surface) perpendicular to the Z direction.

The stage 10 is, for example, a table where the mounting surface F1 has a substantially flat disk shape, and a vacuum chuck is provided on the mounting surface F1. The stage 10 adsorbs a wafer 12 placed on the mounting surface F1 in a vacuum to stably hold the wafer 12. The stage 10 is configured to be rotatable in the horizontal surface (X-Y surface) around a rotation axis 10a that passes through the center of the stage 10 and extends in the vertical direction.

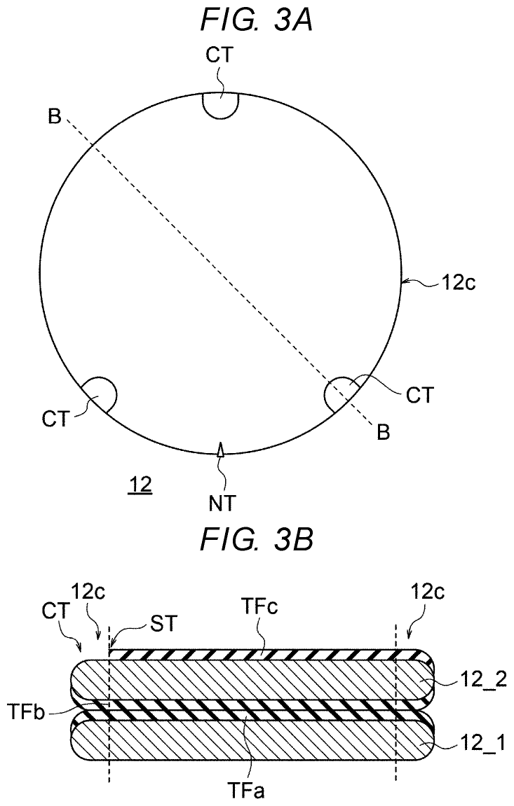

The wafer 12 is a semiconductor substrate such as a silicon substrate having a substantially disk shape and may be a single wafer 12 or may be a bonded wafer in which a plurality of wafers 12_1 and 12_2 are bonded as illustrated in FIG. 3B. The wafer 12 is placed on the stage 10. As illustrated in FIG. 2, the wafer 12 includes a notch NT for specifying a direction (position in a circumferential direction) of the wafer 12.

The cutting unit 20 includes: a cutting blade 22 mounted on a tip portion of a spindle 24; and a blade driving unit 25 that rotates a cutting blade 22 through the spindle 24. The cutting blade 22 is, for example, a very thin ring-shaped cutting grindstone that is formed by bonding a bonding material to an abrasive grain such as diamond. The blade driving unit 25 rotates the cutting blade 22 at a high speed around an axis 24a thereof through the spindle 24, and the cutting blade 22 that is rotating at a high speed is brought into contact with the wafer 12. As a result, the wafer 12 is cut, and a kerf is formed. The cutting unit 20 according to the embodiment executes a trimming process of cutting a part of an outer circumference portion 12c of the wafer 12 in a circumferential direction to remove a chamfered portion. Here, as the cutting blade 22, a thicker blade than that when a linear cutting line (street) between typical semiconductor elements is cut is used.

The cutting unit 20 further includes a cutting unit movement mechanism (not illustrated) and can move in the X, Y, and Z directions. For example, the X direction is a cutting direction. The Y direction is a horizontal direction perpendicular to the cutting direction (X-axis direction) and is an axial direction of the spindle 24 (extending direction of the spindle 24). The Z direction is a cutting depth direction (substantial perpendicular direction). The cutting unit 20 moves in the Y-axis direction such that an edge of the cutting blade 22 can be aligned with a cutting position (cutting line or outer circumference portion) of the wafer 12. The cutting unit 20 moves in the Z-axis direction such that the cutting depth of the cutting blade 22 relative to the wafer 12 can be adjusted.

During cutting, the stage driving unit 45 can rotate the stage 10 around the rotation axis 10a in the horizontal surface. As a result, the wafer 12 held on the stage 10 also rotates around the rotation axis 10a.

The imaging unit 50 (imager) includes an imaging element such as a CCD. The imaging unit 50 is disposed above the outer circumference portion 12c of the wafer 12 and images the wafer 12. The imaging unit 50 images a region including the cutting portion (that is, the outer circumference portion 12c) of the wafer 12 and outputs the obtained image to the control unit 60. As a result, the control unit 60 can specify the direction of the wafer 12 (the position in the circumferential direction) based on the position of the notch NT in FIG. 2.

The control unit 60 controls the respective units of the cutting apparatus 1, for example, the stage 10, the cutting unit 20, and the stage driving unit 45. The control unit 60 functions as an image processing unit that processes the image obtained by the imaging unit 50 for the purposes of the alignment of the wafer 12, the check of the cutting state (chipping) after cutting, and the like.

The cutting apparatus 1 having the above-described configuration may cut one wafer 12. However, recently, in order to reduce the chip size or the package size, the cutting apparatus 1 may also cut the bonded wafer in which a plurality of wafers 12 are joined (bonded).

The cutting apparatus 1 cuts a part of the outer circumference portion 12c of the wafer 12 in the circumferential direction while rotating the stage 10. The cutting apparatus 1 cuts the outer circumference portion 12c in the substantially perpendicular direction from a front surface of the wafer 12 toward the mounting surface F1 to remove at least a part of a R shape of the outer circumference portion 12c (trimming). As a result, subsequently, if a back surface of the wafer 12 is ground by a grinder or the like until the thickness of the wafer 12 is less than the cutting depth, an edge angle of the outer circumference portion 12c of the wafer 12 (angle of a side surface with respect to the front surface and the back surface of the wafer 12) is substantially 90 degrees and is not an acute angle shape. As a result, the cracking and chipping of the outer circumference portion 12c of the wafer 12 can be reduced.

On the other hand, in a film forming step of forming a material film on the front surface or the back surface of the wafer 12, in order to hold the wafer 12 on the stage of the film forming apparatus, a holding tool (not illustrated) may come into partial contact with the outer circumference portion 12c of the wafer 12. In the portion of the front surface or the back surface of the wafer 12 in contact with the holding tool, the material film is not formed, and a contact trace of the holding tool remains.

FIG. 3A is a schematic plan view illustrating the wafer 12 having a contact trace of the holding tool of the film forming apparatus. FIG. 3B is a schematic cross-sectional view taken along line B-B of FIG. 3A. In at least one embodiment, the wafer 12 is a bonded wafer in which a plurality of wafers 12_1 and 12_2 are bonded. Hereinafter, the wafer 12 will also be referred to as “bonded wafer”, and the wafers 12_1 and 12_2 will also simply be referred to as “wafer”.

As illustrated in FIG. 3A, a contact trace CT is provided in the outer circumference portion 12c of the bonded wafer 12. The contact trace CT is a region of the outer circumference portion 12c that comes into contact with the support tool of the film forming apparatus in a film forming step of a material film TFc. Accordingly, the contact trace CT is formed at a position of the holding tool of the film forming apparatus, and the number of contact traces CT to be formed is the same as the number of holding tools. For example, in the example of FIG. 3A, three holding tools are provided in the film forming apparatus, and three contact traces CT are formed at corresponding positions of the outer circumference portion 12c of the bonded wafer 12. The contact trace CT as a first region is a region where the material film TFc is not formed on a surface of the outer circumference portion 12c of the wafer 12_2 facing the mounting surface F1 of the stage 10.

The material film TFc may be a material film that is formed on the back surface of the wafer 12_2 when a material film TFb is formed on the wafer 12_2. Accordingly, the material film TFc is a film that is removed in a subsequent backgrinding step of the wafer 12_2. For example, the wafers 12_1 and 12_2 include semiconductor elements on surfaces facing each other, and when the wafers 12_1 and 12_2 are bonded to each other, the semiconductor elements or wirings thereof are electrically connected to each other. When at least one embodiment is applied to a semiconductor memory, for example, a memory cell array (not illustrated) is formed on a bonding surface of the wafer 12_1, and a complementally metal-oxide-semiconductor (CMOS) circuit (not illustrated) that controls the memory cell array is formed on a bonding surface of the wafer 12_2. Here, a material film TFa may be an interlayer insulating film or a passivation film that covers the memory cell array of the wafer 12_1, and a part of the wiring connected to the memory cell array is exposed from the material film TFa. The material film TFb may be an interlayer insulating film or a passivation film that covers the CMOS circuit of the wafer 12_2, and a part of the wiring connected to the CMOS circuit is exposed from the material film TFb. By bonding the wafers 12_1 and 12_2 to each other, the memory cell array of the wafer 12_1 and the CMOS circuit of the wafer 12_2 are electrically connected to each other via the wiring. While cutting a part of the outer circumference portion 12c of the bonded wafer 12 in a trimming step such that the memory cell array remains on the CMOS circuit, the wafer 12_1 is thinned by backgrinding or the like. As a result, a semiconductor memory in which the memory cell array is provided on the CMOS circuit as a controller is formed. Therefore, the material film TFc may be removed by backgrinding or the like.

As illustrated in FIG. 3B, at the position of the contact trace CT, the material film TFc that is formed by the film forming apparatus is not provided such that the material film or the wafer 12_2 below the material film TFc is exposed. The material films TFa, TFb, and TFc may be, for example, a silicon oxide film or a silicon nitride film and may be, for example, an interlayer insulating film or a protective film (passivation film). The wafers 12_1 and 12_2 have roundness (bevel portion) having a given curvature on the side surface of the outer circumference portion 12c. Accordingly, in a region having no contact trace CT, the material film TFc surrounds the side surface of the wafer 12 in the outer circumference portion 12c, and the thickness of the material film TFc gradually decreases toward the outside of the wafers 12_1 and 12_2. On the other hand, in the region having the contact trace CT, the material film TFc is absent, and a step portion ST is formed.

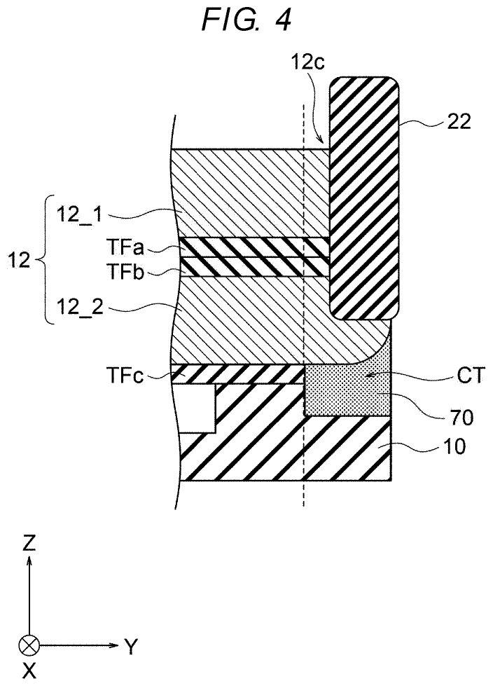

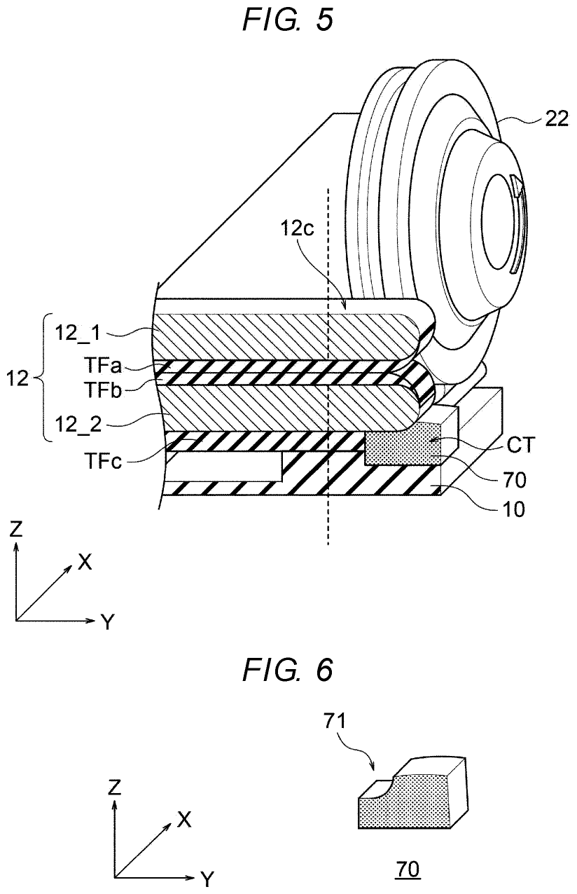

FIG. 4 is a schematic cross-sectional view illustrating a state of the trimming step of the bonded wafer 12 according to the first embodiment. FIG. 5 is a schematic perspective view illustrating the state of the trimming step of the bonded wafer 12 according to the first embodiment.

The cutting apparatus 1 according to the embodiment cuts a part of the outer circumference portion 12c of the bonded wafer 12 (a portion above the outer circumference portion 12c of the wafer 12_1 and the outer circumference portion 12c of the wafer 12_2) placed on the stage 10 using the cutting blade 22. In at least one embodiment, the bonded wafer 12 is placed such that the front surface of the wafer 12_1 to be thinned in the subsequent backgrinding step faces upward (+Z direction). In a region of the stage 10 corresponding to the contact trace CT of the wafer 12_2, a space is formed between the surface of the stage 10 and the outer circumference portion 12c of the wafer 12. In the space, a pad 70 is provided.

The pad 70 is provided between the contact trace CT of the wafer 12_2 and the stage 10. The pad 70 is disposed opposite to the blade 22 with respect to the outer circumference portion 12c of the wafer 12_2 and is provided directly under the contact trace CT of the outer circumference portion 12c. As a result, the pad 70 functions as a spacer that embeds the space of the contact trace CT between the stage 10 and the outer circumference portion 12c, and functions as a support unit that supports the outer circumference portion 12c in the contact trace CT. It is preferable that the pad 70 has a lower elastic modulus than the wafer 12_2 or the material film TFc such that the bonded wafer 12 or the material film TFc is not damaged. Typically, the stage 10 is formed of a material having a high elastic modulus in order to reliably support the bonded wafer 12 while securing flatness during trimming. As the stage 10, for example, a material such as ceramic, stone, or metal is used. On the other hand, it is preferable that the pad 70 has a lower elastic modulus than the stage 10 such that the wafer 12_2 or the material film TFc in contact with the pad 70 is not damaged. As the pad 70, for example, a material such as resin is used.

FIG. 6 is a schematic perspective view illustrating a configuration example of the pad 70. The pad 70 has a substantially cuboidal shape having a recess 71 at one side or corner to be suitable for the curvature of the bevel portion of the outer circumference portion 12c. The shape of the recess 71 corresponds to the shape of the bevel portion of the outer circumference portion 12c of the wafer 12_2. The length of the pad 70 in the X direction is, for example, about 30 to 50 mm, the length of the pad 70 in the Y direction is, for example, about 5 to 10 mm, and the height of the pad 70 in the Z direction is, for example, about 2 to 3 mm. The curvature of the portion of the recess 71 is, for example, 1/r=about 1/(1 mm) to 1/(2 mm).

Referring back to FIGS. 4 and 5, the pad 70 is provided corresponding to the contact trace CT. For example, the positions and number of the contact traces CT are determined depending on the positions and number of the holding tools of the film forming apparatus. Accordingly, if the positions and number of the holding tools of the film forming apparatus are determined, the position coordinates of the contact trace CT can be expressed by (X, Y) coordinates based on the position of the notch NT of the bonded wafer 12. Based on the position coordinates of the contact trace CT, a step or a groove is formed in the stage 10, and the pad 70 is disposed in the step or the groove. As a result, in the trimming step, if the position of the notch NT is aligned with a predetermined position and the bonded wafer 12 is placed on the stage 10, the pad 70 can be made naturally suitable for the contact trace CT of the wafer 12_2 and can support the outer circumference portion 12c of the wafer 12_2 in the contact trace CT. That is, the position coordinates (X,Y) of the contact trace CT are clarified in advance. Therefore, when the position of the notch NT on the stage 10 is set as a predetermined position, the pad 70 can embed the space that is formed by the contact trace CT between the stage 10 and the wafer 12_2 and can support the bonded wafer 12. As a result, in the trimming step of the outer circumference portion 12c, the cracking or chipping of the bonded wafer 12 caused by a cutting pressure or impact of the cutting blade 22 can be reduced.

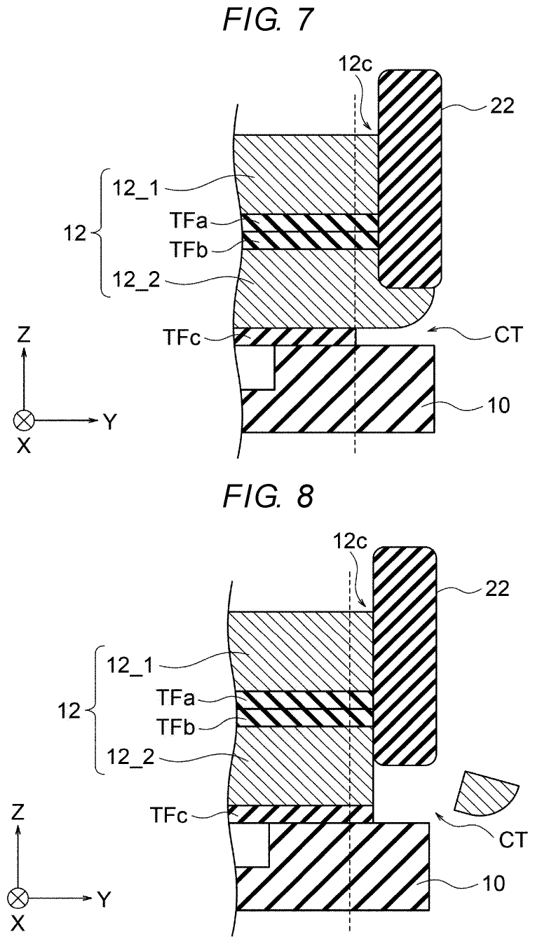

FIGS. 7 and 8 are schematic cross-sectional views illustrating a state of a trimming step according to a comparative example. In the comparative example, the pad 70 is not provided. If the pad 70 is not provided, as illustrated in FIG. 7, the contact trace CT remains as a space between the outer circumference portion 12c of the wafer 12_2 and the stage 10. Here, in the trimming step, as the cutting blade 22 cuts the outer circumference portion 12c, the remainder of the outer circumference portion 12c of the wafer 12_2 at the position of the contact trace CT is pressed in the −Z direction, and a lower end of the wafer 12_2 in the contact trace CT may be damaged by cracking or chipping as illustrated in FIG. 8. Such damage disables the subsequent conveyance and process of the bonded wafer 12, which leads to a decrease in yield.

On the other hand, the cutting apparatus 1 according to at least one embodiment illustrated in FIGS. 4 and 5 includes the pad 70 that is provided between the contact trace CT of the outer circumference portion 12c cut by the cutting blade 22 and the stage 10. The pad 70 supports the wafer 12_2 in the contact trace CT. Thus, the press force from the cutting blade 22 can be dispersed, and the cracking or chipping of the remainder of the outer circumference portion 12c of the wafer 12_2 can be reduced. As a result, the cutting blade 22 can cut the outer circumference portion 12c of the bonded wafer 12 up to a given depth (position in the Z direction).

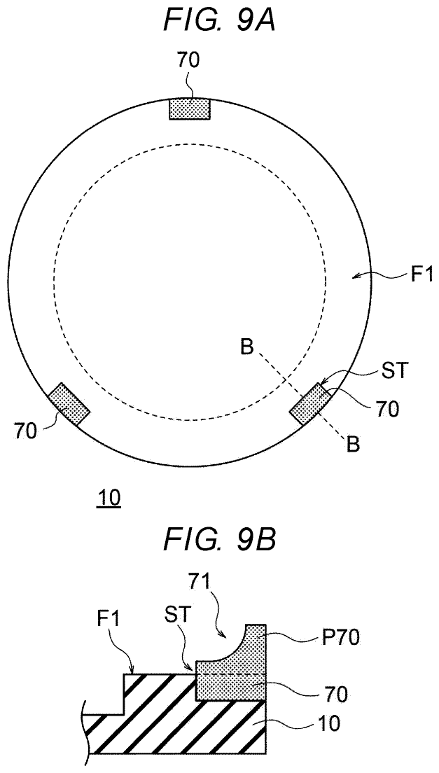

FIG. 9A is a schematic plan view illustrating a configuration example of the stage 10 according to the first embodiment. FIG. 9B is a cross-sectional view taken along line B-B of FIG. 9A. The stage 10 includes the pad 70 at a position corresponding to the contact trace (first region) CT of the wafer 12_2. In the embodiment, as illustrated in FIG. 3A, the contact trace CT is provided at each of three positions of the outer circumference portion 12c. Accordingly, as illustrated in FIG. 9A, the step portion ST is provided at each of three positions of the outer circumference portion of the stage 10, and the pad 70 is fixed to the step portion ST. The pad 70 is adsorbed on and fixed to the step portion ST using a vacuum chuck or may be bonded or fixed thereto using a double-sided tape.

As illustrated in FIG. 9B, the pad 70 protrudes from the mounting surface F1 of the stage 10. In a protrusion portion P70 of the pad 70, the recess 71 is formed at a side or a corner such that the space between the contact trace CT and the mounting surface F1 of the stage 10 can be embedded. The recess 71 is recessed at a curvature corresponding to the roundness of the bevel portion of the wafer 12_2.

It is preferable that the height of the protrusion portion P70 is substantially the same or slightly higher than a gap in the Z direction between the mounting surface F1 and the contact trace CT of the wafer 12. An appropriate height of the protrusion portion P70 depends on the elastic modulus of the pad 70. Originally, the pad 70 is less than the gap between the mounting surface F1 and the contact trace CT of the wafer 12, and may have a function of compensating for the flatness of the wafer 12 by being expanded by heat or light after the mounting of the wafer 12.

FIGS. 10 to 12 are schematic cross-sectional views illustrating steps after the trimming of the outer circumference portion 12c. As illustrated in FIG. 10, the outer circumference portion 12c of the bonded wafer 12 is cut up to a predetermined depth by trimming. In the step, a lower portion of the outer circumference portion 12c of the wafer 12_2 remains. As a result, the conveyance of the bonded wafer 12 and other processes can be executed.

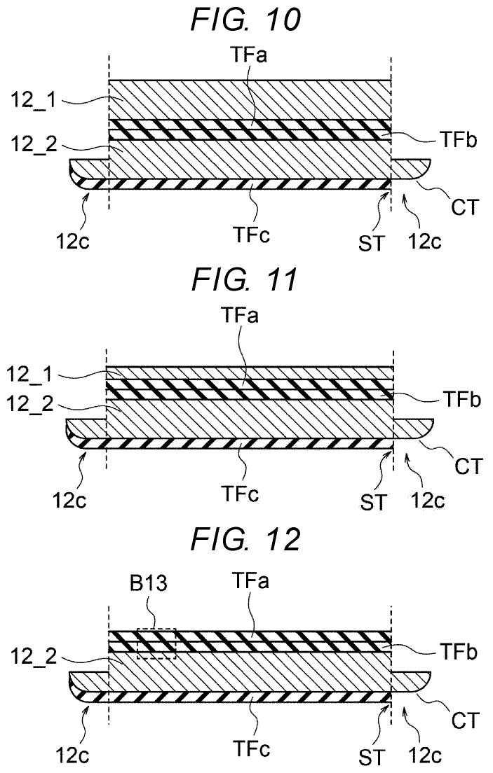

Next, as illustrated in FIG. 11, the wafer 12_1 is polished from the back surface of the wafer 12_1 to thin the wafer 12_1 (backgrinding step). As a result, as illustrated in FIG. 12, a structure where the material films TFa and TFb are provided on the wafer 12_2 can be obtained.

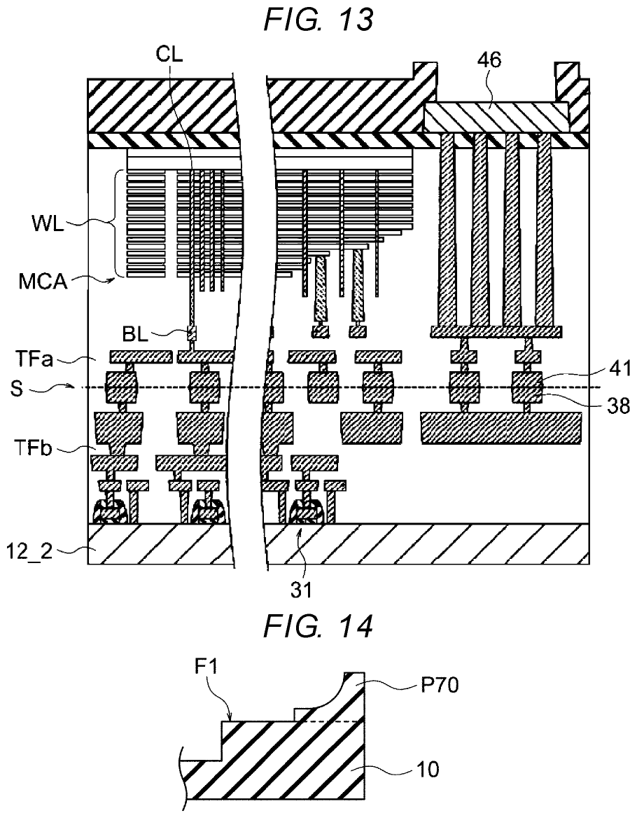

FIG. 13 is a schematic cross-sectional view illustrating an example of an internal configuration of a broken line frame B13 in FIG. 12. A CMOS circuit 31 is provided on the wafer 12_2. The material film (interlayer insulating film) TFb covers the CMOS circuit 31. A wiring 38 electrically connected to the CMOS circuit 31 is exposed from the material film TFa in a bonding surface S.

A memory cell array MCA is provided above the CMOS circuit 31. The memory cell array MCA includes a plurality of memory cells at positions corresponding to intersections between word lines WL and semiconductor columns CL connected to bit lines BL. The memory cells are three-dimensionally arranged. The material film (interlayer insulating film) TFa covers the memory cell array MCA. A wiring 41 electrically connected to the memory cell array MCA is exposed from the material film TFa in the bonding surface S. The material films TFa and TFb are bonded to each other in the bonding surface S, and the wirings 38 and 41 are connected to each other in the bonding surface S.

The embodiment can be applied to the trimming step of the bonded wafer 12 of the semiconductor memories bonded as described above.

The embodiment can be applied not only to the contact trace CT of the support tool in the film forming step but also to unnecessary etching of the back surface of the wafer 12_2 occurring in a reactive ion etching (RIE) method.

### Modification Example

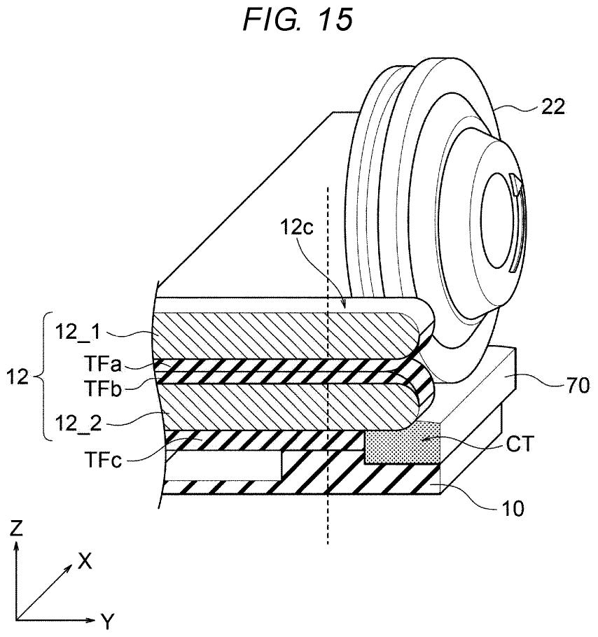

FIG. 14 is a schematic cross-sectional view illustrating a configuration example of the stage 10 according to a modification example of the first embodiment. FIG. 14 illustrates a cross-section of a portion corresponding to FIG. 9B of the first embodiment.

In the first embodiment, the pad 70 is formed separately from the stage 10 and is fixed to the step portion ST of the Stage 10.

On the other hand, in the modification example, the pad 70 is integrated with the stage 10. Here, the pad 70 is formed of the same material as that of the stage 10 and is continuous as apart of the stage 10. The protrusion portion P70 protrudes from the mounting surface F1 as a part of the stage 10. Therefore, the stage 10 according to the modification example includes the protrusion portion P70 that is provided at the position corresponding to the contact trace CT of the wafer 12.

Even with such configuration, the effects of the first embodiment can be obtained. In the modification example, the pad 70 does not need to be formed in addition to the stage 10. Therefore, the steps of forming the stage 10 and the protrusion portion P70 can be simplified and reduced in time.

### Second Embodiment

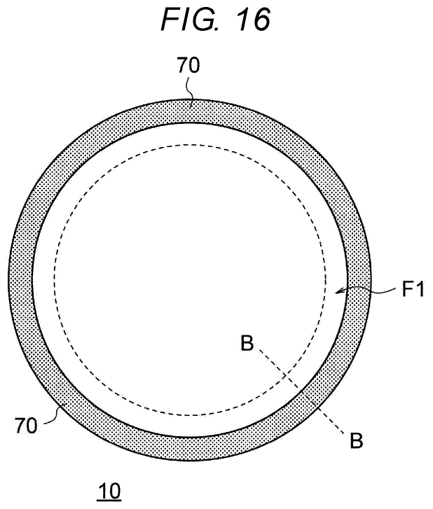

FIG. 15 is a schematic perspective view illustrating a state of a trimming step of the wafer 12 using the cutting apparatus 1 according to a second embodiment. FIG. 16 is a schematic plan view illustrating a configuration example of the stage 10 according to the second embodiment. The cross-section taken along line B-B of FIG. 16 is the same as the cross-section illustrated in FIG. 9B.

In the stage 10 of the cutting apparatus 1 according to the second embodiment, the pad 70 is provided over the entirety of the outer circumference portion of the stage 10. That is, the pad 70 is provided at all the positions on the mounting surface F1 of the stage 10 corresponding to the outer circumference portion 12c of the wafer 12_2. As a result, even when the positions or number of the contact traces CT in the outer circumference portion 12c of the wafer 12_2 is changed, the pad 70 can correspond to any number of contact traces CT at any positions of the outer circumference portion 12c. As a result, the cutting apparatus 1 according to the second embodiment can trim the wafer 12 formed by various kinds of film forming apparatuses while reducing the cracking or chipping of the wafer 12.

The above-described modification example may be applied to the second embodiment. That is, the protrusion portion P70 illustrated in FIG. 14 may be provided at all the positions on the mounting surface F1 of the stage 10 corresponding to the outer circumference portion 12c of the wafer 12_2. As a result, in the second embodiment, the effects of the above-described modification example can also be obtained.

### Third Embodiment

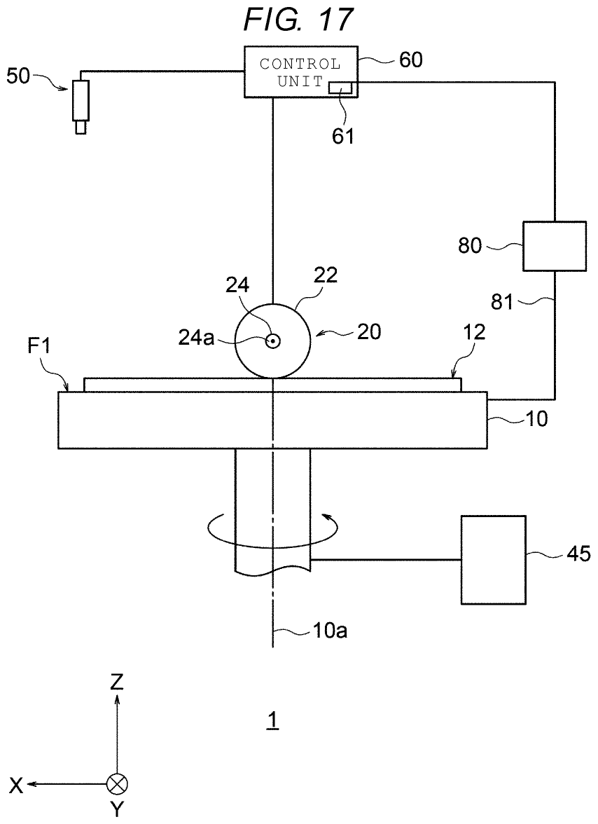

FIG. 17 is a schematic front view illustrating a configuration example of the cutting apparatus 1 according to a third embodiment. The third embodiment may further include a protrusion mechanism 80 that drives the pad 70 to protrude from the mounting surface F1 of the stage 10. The protrusion mechanism 80 receives an instruction of the control unit 60 and controls the pad 70 such that the pad 70 protrudes from the mounting surface F1 of the stage 10 at a position corresponding to the contact trace CT of the wafer 12. The position coordinates of the contact trace CT are stored in a memory 61. The protrusion mechanism 80 acquires position coordinates of the contact trace CT from the memory 61 and drives the pad 70 at a position corresponding to the position coordinates to protrude.

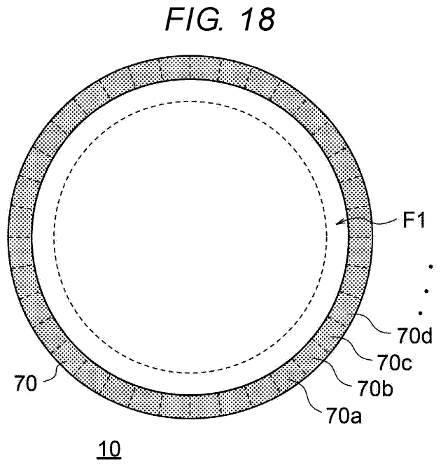

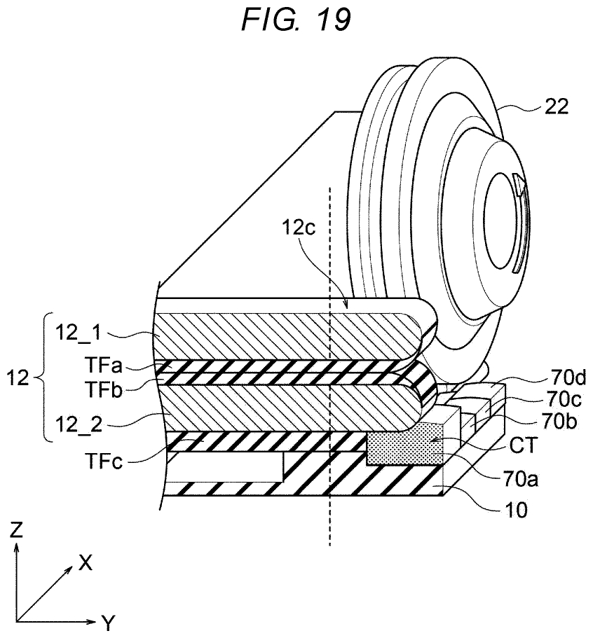

FIG. 18 is a schematic plan view illustrating a configuration example of the stage 10 according to the third embodiment. FIG. 19 is a schematic perspective view illustrating a state of a trimming step of the bonded wafer 12 according to the third embodiment.

The pad 70 includes a plurality of divided regions 70a, 70b, 70c, and is provided over the entire outer circumference of the stage 10. Each of the regions 70a, 70b, 70c, . . . (hereinafter, referred to as the regions 70a and the like) is driven by the protrusion mechanism 80 to selectively protrude. For example, the pad 70 is formed of a flexible material such as resin, and each of the regions 70a and the like is formed of an air-tightly divided hollow bag. By introducing gas into the regions 70a and the like, the regions 70a and the like selectively expand and protrude from the mounting surface F1 of the stage 10. For example, in FIG. 19, the protrusion mechanism 80 introduces gas into the region 70a such that the region 70a selectively protrudes. On the other hand, the regions 70b to 70d do not protrude.

The protrusion mechanism 80 includes: a pump that feeds gas to any one of the regions 70a and the like; and a pipe 81 that connects the pump and the regions 70a and the like to each other. The protrusion mechanism 80 introduces gas into any one of the regions 70a and the like at a position corresponding to the position coordinates of the contact trace CT to protrude. As a result, even when the positions or number of the contact traces CT in the outer circumference portion 12c of the wafer 12_2 is changed, the protrusion mechanism 80 can drive the regions 70a and the like corresponding to any number of contact traces CT at any positions of the outer circumference portion 12c to protrude. As a result, the cutting apparatus 1 according to the third embodiment can trim the wafer 12_2 formed by various kinds of film forming apparatuses while reducing the cracking or chipping of the wafer 12_2.

The protrusion mechanism 80 drives the pad 70 to protrude using an atmospheric pressure but may drive the pad 70 to protrude using another mechanism. For example, a piezoelectric element may be used for the pad 70. Here, the protrusion mechanism 80 selectively supplies electrical power to the piezoelectric element provided in each of the regions 70a and the like such that any one of the regions 70a and the like selectively protrudes. Even with such configuration, the effects of the third embodiment can be obtained.

While certain embodiments have been described these embodiments have been presented by way of example only, and are not intended to limit the scope of the disclosure. Indeed, the novel embodiments described herein may be embodied in a variety of other forms: furthermore various omissions, substitutions and changes in the form of the embodiments described herein may be made without departing from the spirit of the disclosure. The accompanying claims and their equivalents are intended to cover such embodiments or modifications as would fall within the scope and spirit of the disclosure.

What is claimed is:

1. A semiconductor manufacturing apparatus comprising:
a stage having a mounting surface, the stage configured to mount a wafer on the mounting surface; and
a blade configured to cut an outer circumference portion of the wafer, wherein
the stage includes a protrusion provided at a position corresponding to a first region, the first region being a region where a material film is not formed on a first surface of the outer circumference portion.

2. The semiconductor manufacturing apparatus according to claim 1, wherein
the protrusion is configured as a portion of a pad disposed between the wafer and the stage in the first region.

3. The semiconductor manufacturing apparatus according to claim 2, wherein
the pad is provided corresponding to a contact trace, the contact trace being in contact with a support tool of a film forming apparatus in a film forming step of the material film.

4. The semiconductor manufacturing apparatus according to claim 1, wherein
the protrusion is integrated with the stage.

5. The semiconductor manufacturing apparatus according to claim 1, wherein
the protrusion is disposed at each position of the mounting surface of the stage corresponding to the outer circumference portion of the wafer.

6. The semiconductor manufacturing apparatus according to claim 2, wherein
the pad is disposed at each position of the mounting surface of the stage corresponding to the outer circumference portion of the wafer.

7. The semiconductor manufacturing apparatus according to claim 1, further comprising:
a protrusion driver configured to drive the protrusion to protrude from the mounting surface of the stage;
a memory configured to store position coordinates of the first region of the wafer; and
a controller configured to control the protrusion driver such that the protrusion protrudes at a position corresponding to the position coordinates of the first region.

8. A method of manufacturing a semiconductor device using a semiconductor manufacturing apparatus that includes a stage configured to mount a wafer on a mounting surface, a blade configured to cut an outer circumference portion of the wafer, and a protrusion disposed at a position on the stage corresponding to a first region, the first region being a region where a material film is not formed on a first surface of the outer circumference portion, the method comprising:
mounting the wafer on the stage such that the protrusion corresponds to the first region of the wafer; and
cutting the outer circumference portion of the wafer using the blade.

9. The semiconductor manufacturing apparatus according to claim 1, further including an imager configured to image the wafer.

10. The semiconductor manufacturing apparatus according to claim 1, wherein the blade includes a ring-shaped grindstone.

11. The semiconductor manufacturing apparatus according to claim 2, wherein the pad is fixed to the stage via step portions of the stage.

12. The semiconductor manufacturing apparatus according to claim 2, wherein the pad has a lower elastic modulus than the stage.

13. The semiconductor manufacturing apparatus according to claim 2, wherein the pad is formed of resin.

14. The semiconductor manufacturing apparatus according to claim 2, wherein the height of the pad is at least 2 mm and no more than 3 mm.

15. The semiconductor manufacturing apparatus according to claim 7, wherein the controller is configured to control the protrusion based on imaging the wafer.
